(19) United States
(12) Patent Application Publication
(10) Pub. No.: US 2008/0007906 A1
(43) Pub. Date: Jan. 10, 2008

(54) HINGE ASSEMBLY WITH STOP AND DISPLAY MONITOR HAVING SAME

(75) Inventors: SHENG-CHENG HSU, Tu-Cheng (TW); PU LUO, Shenzhen (CN); JIN-SHU XUE, Shenzhen (CN); CHAO-YANG WANG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/560,805

(22) Filed: Nov. 16, 2006

(30) Foreign Application Priority Data
Jul. 7, 2006 (CN) 200610061570.7

(51) Int. Cl. H05K 7/16

(52) U.S. Cl. 361/682

(57) ABSTRACT

A hinge assembly (300) for use in a flat display monitor includes a support member (10), a rotational bracket (20) and a pivot mechanism (30) for rotatably connecting the rotational bracket to the support member. The support member includes an extending seat (16) defining a restricting groove (162) thereof. The pivot mechanism includes a pivotal shaft (301), a torsion spring (302), and a stop (303). The torsion spring is disposed around the pivotal shaft for providing torsion force. The pivotal shaft is fixedly connected to the rotational bracket and rotatably connected to the rotational bracket. The stop is fixed at end of the pivotal shaft and is rotatable in the restricting groove corresponding to rotation of the rotational bracket relative to the support member, with the stop being rotatable between a first utmost position and a second utmost position.

### CROSS-REFERENCE TO RELATED APPLICATIONS

This application is related to co-pending U.S. patent application, entitled “HINGE ASSEMBLY FOR DISPLAY MONITOR”, by Shao-Han Chang. Such application is assigned to the same assignee as the present application, and is filed concurrently with the present application. The disclosure of the above-identified application is incorporated herein by reference.

### BACKGROUND OF THE INVENTION

1. Field of the Invention

The present invention generally relates to hinge assemblies and, particularly, to a hinge assembly for a display monitor such as a flat display monitor.

2. Discussion of the Related Art

With the widespread use of a variety of computers, display devices configured for use with such computers come in different sizes, shapes, and weights. In general, a typical cathode-ray tube (CRT) monitor includes a display panel for displaying images, a vacuum tube coupled to the rear of the display panel, and an electron gun coupled to the rear of the vacuum tube. This configuration is the predominant factor that determines the total volume and final weight of the CRT monitor. In addition, the CRT monitor has a significant drawback, in that a user is easily fatigued when viewing the CRT monitor over several hours due to its low image quality. Because of this problem alone, many users have switched from a CRT monitor to a flat screen display monitor such as a liquid crystal display (LCD) monitor. Such flat display monitors generally offer the advantages of a greatly reduced overall size, reduced weight, and high image quality. Furthermore, flat display monitors may help to overcome space limitations and constrictions through folding over (such as with a laptop computer) or rotating (such as with a desktop monitor) so as to facilitate easy adjustment of the position of a screen the flat display monitor relative to the user.

The rotating or folding-over functions of a flat display monitor are usually realized with a hinge assembly. A typical hinge assembly includes an L-shaped fixed seat, a pivotal axle, and a number of oil washers. The fixed seat has a retaining hole defined therein. The pivotal axle is pivotally connected with the fixed seat. The pivotal axle has a retaining shoulder formed at a middle portion thereof, a connecting end portion integrally formed at a first end of the retaining shoulder, and a fixing end portion integrally formed at a second end of the retaining shoulder. The connecting end portion of the pivotal axle extends through a retaining hole of the fixed seat along with the oil washers, and is fastened in the fixed seat by a fastening piece. The hinge assembly limits a maximum inclination angle of the flat display monitor by means of the configuration of the retaining hole in the fixed seat. However, in general, a high degree of precision is required in manufacturing the retaining hole, and this tends to increase the cost of manufacturing. In addition, edges of the fixed seat around the retaining hole are liable to be abraded. As a result, the flat display monitor might be rotated beyond the maximum inclination angle, and/or the flat display monitor may not remain stable at the inclination angle selected by a user. Furthermore, during use, a user may need to exert great effort on the flat display monitor in order to be able to rotate the hinge assembly.

Therefore, a new hinge assembly is desired in order to overcome the above-described shortcomings.

### SUMMARY

In one embodiment, a hinge assembly for use in a flat display monitor includes a support member, a rotational bracket and a pivot mechanism for rotatably connecting the rotational bracket to the support member. The support member includes an extending seat defining a restricting groove thereof. The pivot mechanism includes a pivotal shaft, a torsion spring, and a stop. The torsion spring is disposed around the pivotal shaft for providing torsion force. The pivotal shaft is fixedly connected to the rotational bracket and rotatably connected to the rotational bracket. The stop is fixed the pivotal shaft and is rotatable in the restricting groove corresponding to rotation of the rotational bracket relative to the support member, with the stop being rotatable between a first utmost position at which the stop is blocked by a first portion of the extending seat, and a second utmost position at which the stop is blocked by a second portion of the extending seat.

Other advantages and novel features will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of the present hinge assembly and display monitor. Moreover, in the drawings, like reference numerals designate corresponding parts throughout the several views.

FIG. 1 is an isometric view of a flat display monitor incorporating a hinge assembly (shown in phantom) in accordance with one embodiment of the present invention.

FIG. 2 is an enlarged, exploded, isometric view of the hinge assembly of FIG. 1, viewed from another aspect.

FIG. 3 is an assembled view of the hinge assembly shown in FIG. 2, but viewed from another aspect, and showing a rotational bracket of the hinge assembly rotated to a first utmost position.

FIG. 4 is similar to FIG. 3, but showing the rotational bracket of the hinge assembly rotated to a second utmost position.

FIG. 5 is a cross-sectional view taken along line V-V of FIG. 3.

### DETAILED DESCRIPTION OF THE EMBODIMENTS

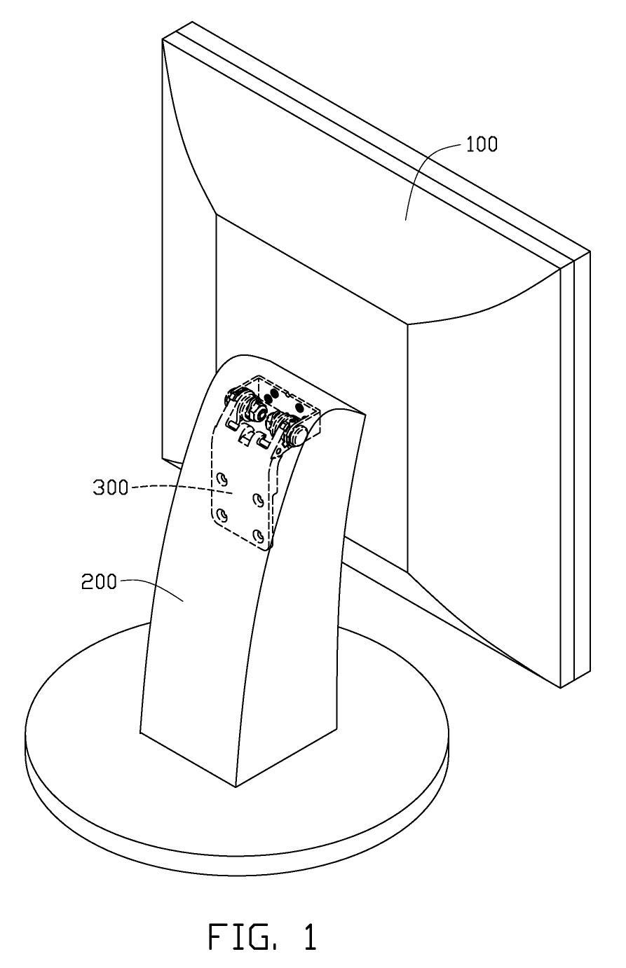

Referring to the drawings in detail, FIG. 1 shows a flat display monitor employing a hinge assembly 300 in accordance with one embodiment of the present invention. The flat display monitor is taken here as an exemplary application, for the purposes of describing details of the hinge assembly 300. Thus, although the hinge assembly 300 provides particular advantages when used in a flat display monitor, the hinge assembly 300 should not be considered to be limited in scope to uses in the field of flat display monitors. The exemplary flat display monitor herein also includes a display body 100 and a support body 200. The hinge assembly 300 connects the display body 100 to the support body 200, such that the display body 100 can be pivoted relative to the support body 200.

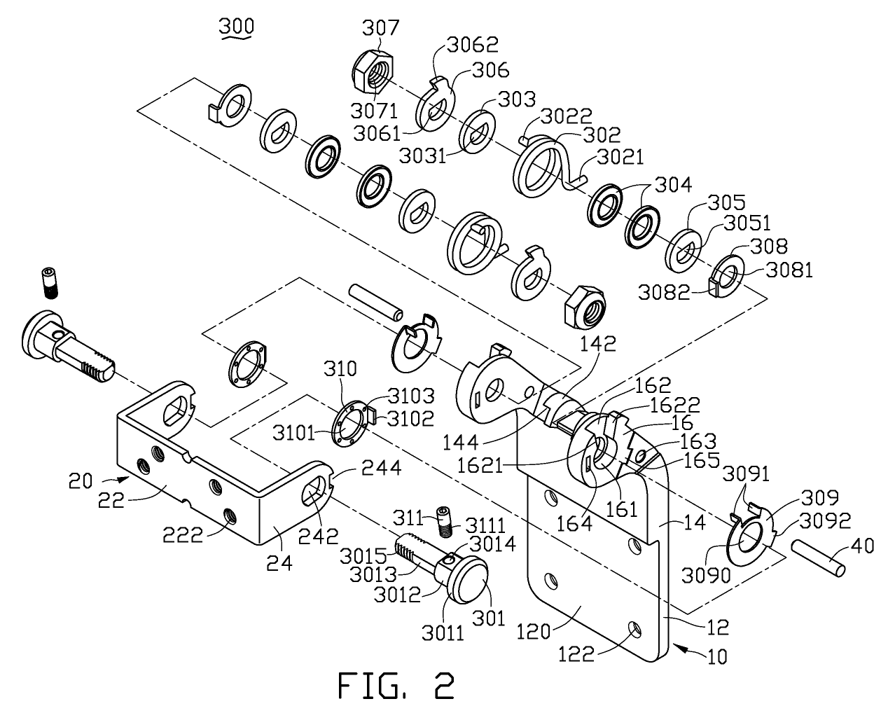

Referring to FIG. 2, the hinge assembly 300 includes a support member 10, a rotational bracket 20, and two pivot mechanisms (not labeled). The support member 10 is configured to be fixed to the support body 200, and the rotational bracket 20 is configured to be fixed to the display body 100. The pivot mechanism is used for connecting the support member 10 and the rotational bracket 20, so that the rotational bracket 20 can rotate relative to the support member 10.

The support member 10 includes a mounting portion 12, a connecting portion 14, and two extending seats 16. The mounting portion 12 and the connecting portion 14 are substantially board-shaped, with the connecting portion 14 being thicker than the mounting portion 12. The mounting portion 12 has a surface 120, and defines a plurality of mounting holes 122. In this embodiment, there are four mounting holes 122. The support member 10 is mounted to the support body 200 by means of the mounting holes 122. One end of the connecting portion 14 integrally connects with the mounting portion 12, and an opposite end of the connecting portion 14 forms a central protrusion 142. The protrusion 142 defines two fixing slots 144 at two opposite sides thereof. Each of the fixing slots 144 is generally located at a side of the protrusion 142 nearest to the surface 120. The extending seats 16 extend from said opposite end of the connecting portion 14, and are located at opposite sides of the protrusion 142 respectively. The extending seats 16 generally bend toward a same direction that is substantially perpendicular to the surface 120. The extending seats 16 are parallel to each other, and are spaced apart from the protrusion 142. A main body of each extending seat 16 is substantially cylindrical, and defines a central pivoting hole 161, a restricting groove 162, a through hole 163, a fixing hole 164, and a fixing groove 165. The central pivoting hole 161 is a round, stepped hole running though a middle portion of the extending seat 16. The restricting groove 162 has a generally truncated sector shape, with the truncated end of the restricting groove 162 communicating with the central pivoting hole 161. The restricting groove 162 is bounded by a first restricting surface 1621 and an opposite second restricting surface 1622, which are configured for restricting maximum inclination angles of the rotational bracket 20. The through hole 163 is a round hole adjacent to the connecting portion 14, and is for receiving a corresponding one of two pins 40. The fixing hole 164 is a rectangular hole defined adjacent to a distal end of the extending seat 16. The fixing groove 165 is a rectangular groove defined in a thickened portion of the extending seat 16, and is generally between the through hole 163 and the central pivoting hole 161. The central pivoting holes 161 of the extending seats 16 are coaxial.

The rotational bracket 20 includes a fixing board 22 and two opposite side boards 24. The fixing board 22 defines a plurality of threaded assembling holes 222. In this embodiment, there are four assembling holes 222. The rotational bracket 20 is mounted to the display body 100 by means of utilizing the assembling holes 222. The side boards 24 perpendicularly extend from two opposite ends of the fixing board 22 respectively. Each of the side boards 24 defines an engaging hole 242 and a fixing groove 244. The engaging hole 242 has a keyed configuration with straight extremities. In the illustrated embodiment, the engaging hole 242 is shaped as a very short slot with rounded ends. The fixing groove 244 is defined in a distal end of the fixing board 22.

Each pivot mechanism includes a pivotal shaft 301, a torsion spring 302, a first washer 303, a pair of resilient springs 304, a second washer 305, a limiting washer 306, a fixing piece 307, a first tab washer 308, a second tab washer 309, a third tab washer 310, and a stop pin 311.

The pivotal shaft 301 includes a flange 3011, a first keyed portion 3012, and a second keyed portion 3013. The flange 3011 is substantially disk-like in shape. The first keyed portion 3012 is generally cylindrical, but with two opposite, parallel flattened sides. A diameter of the first keyed portion 3012 is larger than that of the second keyed portion 3013. A cross-section of the first keyed portion 3012 corresponds to the shape and size of each engaging hole 242 of the rotational bracket 20. The first keyed portion 3012 defines a transverse thread hole 3014 spanning between the parallel flat sides. The second keyed portion 3013 is generally cylindrical, but with one flattened side. Thus a cross-section of second keyed portion 3013 is generally “D” shaped. The second keyed portion 3013 defines a thread 3015 on a distal end portion thereof. Because of the flattened side, the thread 3015 although being regular is also discontinuous.

The torsion spring 302 is helical, and has a first latching end 3021 and a second latching end 3022. The first latching end 3021 is bent from one end of a main body of the torsion spring 302, and generally lies in a plane perpendicular to a central axis of the torsion spring 302. The second latching end 3022 is bent from an opposite end of the main body of the torsion spring 302, and extends along a direction parallel to the axis of the torsion spring 302. A diameter of the torsion spring 302 is larger than that of each of the first washer 303, the resilient springs 304, and the second washer 305. When the hinge assembly 300 is assembled, the torsion spring 302 exerts a predetermined torsion force (see below).

The first and second washers 303 and 305 are approximately ring-shaped. The first and second washers 303 and 305 define a latching hole 3031 and 3051 respectively. Each of the latching holes 3031 and 3051 has a shape and size corresponding to the cross-section of the second keyed portion 3013 of each pivotal shaft 301. That is, the latching holes 3031 and 3051 are generally “D” shaped.

The resilient springs 304 are typically in the form of elastic washers. The resilient springs 304 are configured to provide axial forces.

The limiting washer 306 is approximately ring-shaped, and defines a latching hole 3061 in a middle portion thereof. The latching hole 3061 has a shape and size corresponding to each engaging hole 242 of the rotational bracket 20. The limiting washer 306 forms a limiting block 3062 at a periphery thereof. The limiting block 3062 is generally involute relative to a main body of the limiting washer 306.

The fixing piece 307 is typically a screw nut defining a thread 3071 therein, for engaging with the thread 3015 of the corresponding pivotal shaft 301.

The first tab washer 308 is approximately ring-shaped, and defines a round hole 3081 in a middle portion thereof. A tab 3082 is formed at a periphery of the first tab washer 308. The tab 3082 has a shape and size corresponding to each fixing hole 164 of the support member 10.

The second tab washer 309 is configured for preventing a corresponding extending seat 16 of the support member 10 from directly touching a corresponding side board 24 of the rotational bracket 20, so that the extending seat 16 and the side board 24 are not easily worn down. The second tab washer 309 defines a round hole 3090 in a middle portion thereof. A pair of protecting pieces 3091 extends from a peripheral portion of the second tab washer 309, parallel to an axial direction of the second tab washer 309. The protecting pieces 3091 are configured for engaging in a corresponding restricting groove 162 of the support member 10. A tab 3092 is formed at a periphery of the second tab washer 309.

The third tab washer 310 is substantially the same as the first tab washer 308 and is also approximately ring-shaped. However, the third tab washer 310 defines a round hole 3101 in a middle portion thereof, and a plurality of evenly spaced lubricating holes 3103 around the round hole 3090. The lubricating holes 3103 are configured for storing lubricating oil. A tab 3102 is formed at a periphery of the third tab washer 310. The tab 3102 has a shape and size corresponding to each fixing groove 244 of the rotational bracket 20.

The stop pin 311 is cylindrical in shape. The stop pin 311 defines a thread 3111 on a distal end portion thereof, for engaging in the thread hole 3014 of a corresponding pivotal shaft 301.

Each pin 40 is cylindrical in shape. The pin 40 has a size substantially the same as that of each through hole 163 of the support member 10.

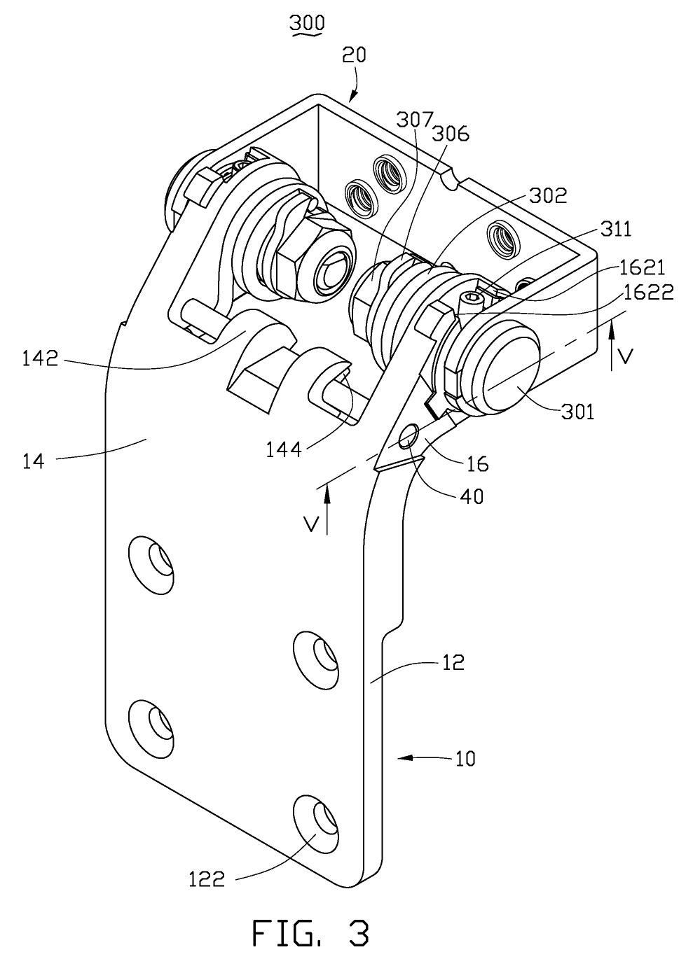

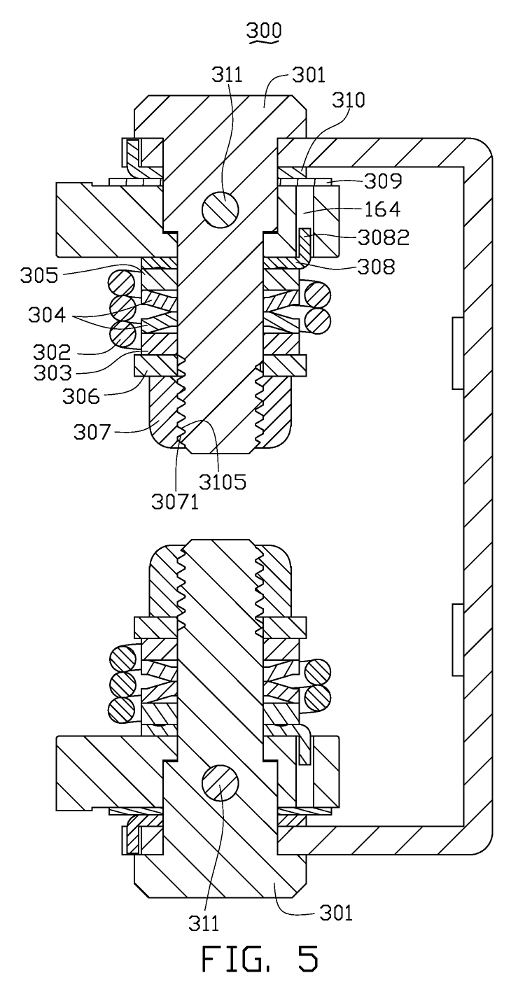

Referring now to FIGS. 3-5, in assembly of each pivot mechanism 30, the pin 40 is inserted through the through hole 163 of the corresponding extending seat 16 of the support member 10. One end of the pin 40 is received in the corresponding fixing slot 144 of the support member 10. The first tab washer 308 is fixed to the extending seat 16, with the tab 3082 of the first tab washer 308 being received in the fixing hole 164. The second tab washer 309 is fixed to the extending seat 16. The two protecting pieces 3091 of the second tab washer 309 are engaged in the restricting groove 162 so as to respectively abut the first restricting surface 1621 and the second restricting surface 1622. The tab 3092 of the second tab washer 309 is received in the fixing groove 165. The third tab washer 310 is fixed to the corresponding side board 24 of the rotational bracket 20, with the tab 3102 of the third tab washer 310 being received in the fixing groove 244. The rotational bracket 20 is positioned around an end of the support member 10. The engaging holes 242 of the side boards 24 of the rotational bracket 20 are aligned with the central pivoting holes 161 of the support member 10, with the side boards 24 of the rotational bracket 20 disposed at exterior sides of the extending seats 16 of the support member 10 respectively. The pivotal shaft 301 of each pivot mechanism 30 is passed through the engaging hole 242 of the corresponding side board 24 of the rotational bracket 20, the round hole 3101 of the third tab washer 310, the round hole 3090 of the second tab washer 309, the central pivoting hole 161 of the corresponding extending seat 16, the round hole 3081 of the first tab washer 308, the latching hole 3051 of the second washer 305, the pair of resilient springs 304, the latching hole 3031 of the first washer 303, the torsion spring 302, and the latching hole 3061 of the limiting washer 306, in that order. The two resilient washers 304 abut each other and are oriented symmetrically opposite to each other. The fixing piece 307 is fixed on the pivotal shaft 301 via the threads 3017, 3015 thereof. The stop pin 311 is fixed to the pivotal shaft 30, with the thread 3111 engaging in the thread hole 3014 of the pivotal shaft 301. Thus the first latching end 3021 of the torsion spring 302 resists the pin 40, and the second latching end 3022 of the torsion spring 302 resists the limiting block 3062 of the limiting washer 306. Thereby, one of the pivot mechanisms 30 is assembled. The other pivot mechanism 30 is assembled in a similar manner.

When the hinge assembly 300 is used to assemble the flat display monitor, the support member 10 is fixed to the support body 200 by means of engagement of fasteners in the mounting holes 122. The fasteners can for example be bolts or screws. The rotational bracket 20 is fixed to display body 100 by means of engagement of fasteners in the threaded assembling holes 222. The fasteners can for example be bolts or screws.

In each pivot mechanism 30 of the hinge assembly 300, the first, second, and third tab washers 308, 309 and 310, the first and second washers 303 and 305, the two resilient springs 304, and the limiting washer 306 cooperatively maintain desired spaces between the various components of the pivot mechanism 30. In addition, the first, second, and third tab washers 308, 309, and 310, the first and second washers 303 and 305, the two resilient springs 304, and the limiting washer 306 together cooperatively help provide an amount of friction that allows movement of the display body 100 relative to the support body 200 upon application of a moderate force, and that also allows the display body 100 to be stably maintained in a desired position relative to the support body 200 and the display body 100. Part of the required amount of friction can also be obtained through the operation of the other elements of the hinge assembly 300 as well.

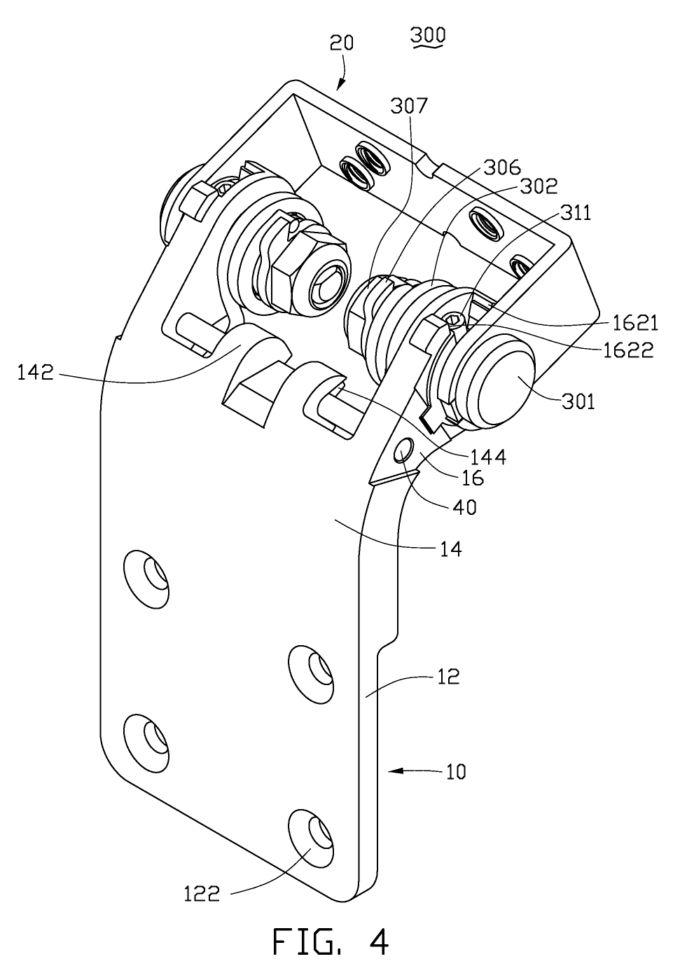

In use, a pushing force is exerted on the display body 100 by a user. Because the support member 10 is fixed relative to the support body 200, the display body 100 in turn causes the rotational bracket 20 to move. In each pivot mechanism 30, the first and second washers 303, 305 and the limiting washer 306 also rotate together with the rotational bracket 20. Accordingly, the second latching end 3022 of the torsion spring 302 which resists the limiting block 3062 of the limiting washer 306 rotates, whereby the torsion force of the torsion spring 302 either increases or decreases. If an initial position of the display body 100 is an intermediate position relative to the support member 10, then the torsion force of the torsion spring 302 increases when the display body 100 rotates in a first direction generally toward the surface 120, and the torsion force of the torsion spring 302 decreases when the display body 100 rotates in a second direction opposite to the first direction. Referring to FIG. 3, when the display body 100 rotates through a determined angle in the first direction to a first utmost position, the stop pin 311 reaches the protecting piece 3091 that abuts the first restricting surface 1621 of the support member 10. Thereby, the display body 100 together with the rotational bracket 20 cannot rotate further in the first direction. Referring to FIG. 4, when the display body 100 rotates through a determined angle in the second direction to a second utmost position, the stop pin 311 reaches the protecting piece 3091 that abuts the second restricting surface 1622 of the support member 10. Thereby, the display body 100 together with the rotational bracket 20 cannot rotate further in the second direction. Thus the hinge assembly 300 limits a maximum inclination angle of the display body 100 in a tilt-down (tilt-forward) direction by the restricting surfaces 1621 of the support member 10, and limits a maximum inclination angle of the display body 100 in a tilt-up (tilt-back) direction by the restricting surfaces 1622 of the support member 10.

In alternative embodiments, each pivotal shaft 301 can fastened by means of other kinds of holding members such as a rivet or a ring. For example, a C-shaped ring and a receiving groove can replace the fixing piece 307 and the thread 3015 of the second keyed portion 3013 of the pivotal shaft 301. Only a single pivot mechanism may be provided. In such case, one of the extending seats 16 of the support member 10 and one of the side boards 24 of the rotational bracket 20 can be configured otherwise, in a way to facilitate rotation of the rotational bracket 20; and one of the pins 40 can be omitted. The pins 40 may be replaced by other resisting members such as bolts, or protrusions formed on the rotational bracket 20. Other elastic members such as other kinds of springs or elastic washers may replace the two resilient springs 304. The support member 10 may be mounted to the display body 100, and accordingly the rotational bracket 20 may be mounted to the support body 200.

As described above, the preferred embodiment provides a hinge assembly 300 for a device such as a flat display screen. The hinge assembly 300 is durable, and makes operation of the flat display screen convenient for a user. It is, however, to be understood that the hinge assembly 300 can be advantageously used in other applications in which it may be desirable to allow selective pivoting over a limited angular range, such as with a free-standing, adjustable mirror, a closed-circuit camera installation, a cabinet door, etc.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A hinge assembly, comprising:
a rotational bracket including a side board defining an engaging hole;
a support member including an extending seat defining a pivoting hole, and a restricting groove communicating with the pivoting hole; and
a pivot mechanism rotatably connecting the rotational bracket to the support member, the pivot mechanism comprising:
a pivotal shaft running through the engaging hole and the pivoting hole so as to be fixedly connected to the side board of the rotational bracket and rotatable in the pivoting hole;
a torsion spring around the pivotal shaft, the torsion spring configured for providing torsion force;
a fixing piece disposed at one end of the pivotal shaft to prevent the torsion spring from disengaged from the pivotal shaft; and
a stop fixed to the pivotal shaft, the stop being rotatable in the restricting groove corresponding to rotation of the rotational bracket relative to the support member, with the stop being rotatable between a first utmost position at which the stop is blocked by a first portion of the extending seat, and a second utmost position at which the stop is blocked by a second portion of the extending seat.

2. The hinge assembly as claimed in claim 1, wherein the restricting groove has a generally truncated sector shape with the truncated end of the restricting groove communicating with the pivoting hole, the restricting groove is bounded by a first restricting surface and an opposite second restricting surface, the first portion of the extending seat comprises the first restricting surface, and the second portion of the extending seat comprises the second restricting surface.

3. The hinge assembly as claimed in claim 1, wherein the pivotal shaft includes a first keyed portion for engaging in the engaging hole of the rotational bracket, and a cross-section of the first keyed portion corresponds to a shape and a size of the engaging hole of the rotational bracket.

4. The hinge assembly as claimed in claim 3, wherein the first keyed portion of the pivotal shaft defines a transverse thread hole therein, the stop is cylindrical and defines a thread thereon, and the stop is fixed to the pivotal shaft by engagement of the thread of the stop in the thread hole.

5. The hinge assembly as claimed in claim 3, wherein the pivotal shaft further includes a flange and a second keyed portion, the first keyed portion is formed between the flange and the second keyed portion, and a diameter of the first keyed portion is larger than that of the second keyed portion.

6. The hinge assembly as claimed in claim 5, wherein the second keyed portion of the pivotal shaft has a generally “D” shaped cross-section and defines a thread on said one end thereof, the fixing piece is a screw nut defining a thread therein, and the screw nut is fixed on said one end of the pivotal shaft by engagement of the thread of the screw nut with the thread of the pivotal shaft.

7. The hinge assembly as claimed in claim 6, wherein the support member further includes a mounting portion and an adjacent connecting portion, and the connecting portion includes the extending seat.

8. The hinge assembly as claimed in claim 7, wherein each of the mounting portion and the connecting portion of the support member is substantially board-shaped, with the connecting portion being thicker than the mounting portion.

9. The hinge assembly as claimed in claim 7, wherein the connecting portion of the support member includes a protrusion defining a fixing slot, the connecting portion of the support member defines a through hole, one end of a pin is received in the through hole and an opposite of the pin is received in the fixing slot, a limiting washer including a limiting block at a periphery thereof is disposed between the torsion spring and the fixing piece, and the torsion spring includes a first latching end resisting the pin and a second latching end resisting the limiting block of the limiting washer.

10. The hinge assembly as claimed in claim 9, further comprising two washers and two resilient springs, wherein said two washers are disposed between the extending seat of the support member and the limiting washer, each of said two washers defines a latching hole receiving the second keyed portion of the pivotal shaft therethrough such that each of said two washers rotates along with rotation of the pivotal shaft, and the resilient springs are disposed between said two washers and provide axial force.

11. The hinge assembly as claimed in claim 9, wherein the extending seat of the support member is substantially cylindrical and defines a fixing hole, a tab washer is fixed to the extending seat, and the tab washer includes a tab engaged in the fixing hole and a hole through which the pivotal shaft extends.

12. The hinge assembly as claimed in claim 9, further comprising a tab washer, wherein the support member defines a fixing groove therein, the tab washer includes a hole and also includes a pair of protecting pieces and a tab extending from a peripheral portion thereof, and the tab washer is fixed to the extending seat, with the pivotal shaft extending through the hole, the tab being engaged in the fixing groove, and the protecting pieces abutting the first and second portions of the extending seat respectively.

13. The hinge assembly as claimed in claim 9, wherein the side board of the rotational bracket defines a fixing groove adjacent to the engaging hole, a tab washer is fixed to the side board, the tab washer includes a hole and a tab, the pivotal shaft extends through the hole, and the tab is engaged in the fixing groove.

14. A display monitor comprising:
a display body;
a support body; and
a hinge assembly including:
a support member fixed to the support body, the support member including a side board defining an engaging hole; a rotational bracket fixed to the display body, the rotational bracket including an extending seat defining a pivoting hole, and a restricting groove communicating with the pivoting hole; and
a pivot mechanism rotatably connecting the rotational bracket to the support member, the pivot mechanism including:
a pivotal shaft running through the engaging hole and the pivoting hole so as to be fixedly connected to the side board of the rotational bracket and rotatable in the pivoting hole;
a torsion spring around the pivotal shaft, the torsion spring configured for providing torsion force;
a fixing piece disposed on one end of the pivotal shaft to prevent the torsion spring from disengaged with the pivotal shaft; and
a stop fixed to of the pivotal shaft, the stop being rotatable in the restricting groove corresponding to rotation of the rotational bracket relative to the support member, with the stop being rotatable between a first utmost position at which the stop is blocked by a first portion of the extending seat, and a second utmost position at which the stop is blocked by a second portion of the extending seat.

15. The display monitor as claimed in claim 14, wherein the restricting groove has a generally truncated sector shape, with the truncated end of the restricting groove communicating with the pivoting hole, the restricting groove is bounded by a first restricting surface and an opposite second restricting surface, the first portion of the extending seat comprises the first restricting surface, and the second portion of the support member comprises the second restricting surface.

16. The display monitor as claimed in claim 15, wherein the pivotal shaft includes a first keyed portion for engaging in the engaging hole of the rotational bracket, and a cross-section of the first keyed portion corresponds to a shape and a size of the engaging hole of the rotational bracket, the first keyed portion of the pivotal shaft defines a transverse thread hole therein, the stop is cylindrical and defines a thread thereon, and the stop is fixed to the pivotal shaft by engagement of the thread of the stop in the thread hole.

17. The display monitor as claimed in claim 16, wherein the pivotal shaft further includes a flange and a second keyed portion, the first keyed portion is formed between the flange and the second keyed portion, a diameter of the first keyed portion is larger than that of the second keyed portion, the second keyed portion of the pivotal shaft has a generally “D” shaped cross-section and defines a thread on said one end thereof, the fixing piece is a screw nut defining a thread therein, and the screw nut is fixed on said one end of the pivotal shaft by engagement of the thread of the screw nut with the thread of the pivotal shaft.

18. The display monitor as claimed in claim 14, wherein the support member further includes a mounting portion and an adjacent connecting portion, the connecting portion includes the extending seat, each of the mounting portion and the connecting portion is substantially board-shaped, with the connecting portion being thicker than the mounting portion.

19. The display monitor as claimed in claim 18, wherein the connecting portion of the support member includes a protrusion defining a fixing slot, the connecting portion of the support member defines a through hole, one end of a pin is received in the through hole and an opposite of the pin is received in the fixing slot, a limiting washer including a limiting block at a periphery thereof is disposed between the torsion spring and the fixing piece, and the torsion spring includes a first latching end bent from one end resisting the pin and a second latching end bent from an opposite end resisting the limiting block of the limiting washer.

20. The display monitor as claimed in claim 18, further comprising a tab washer, wherein the support member defines a fixing groove therein, the tab washer includes a hole and also includes a pair of protecting pieces and a tab extending from a peripheral portion thereof, and the tab washer is fixed to the extending seat, with the pivotal shaft extending through the hole, the tab being engaged in the fixing groove, and the protecting pieces abutting the first and second portions of the extending seat respectively.
